(19) United States
(12) Patent Application Publication
(10) Pub. No.: US 2008/0218233 A1
(43) Pub. Date: Sep. 11, 2008

(54) Master-slave type flip-flop circuit and latch circuit

(75) Inventors: Hiroshi Yamamoto, Kanagawa (JP); Makoto Nonaka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/073,334

(22) Filed: Mar. 4, 2008

(30) Foreign Application Priority Data
Mar. 5, 2007 (JP) 2007-054382

(51) Int. Cl. H03K 3/02; H03K 3/289

(52) U.S. Cl. 327/198; 327/202

(57) ABSTRACT

A clock input circuit 13 receives power during standby mode and comprises a NAND circuit NAND0 that controls a clock signal CK using a standby mode signal RET. When the standby mode signal RET is at a low level (in standby mode) clock signals C01 and C02 are kept at a high level and low level respectively regardless of the level of the clock signal CK. Further, power continues to be supplied to an FA section in the clock input circuit 13 and to an FB section in a slave latch circuit 12 whereas the power supply to the other circuits is shut off. As a result, the clock signals C01 and C02 remain at the high level and low level respectively and data is held by a loop formed by an on-state transfer gate circuit TG4 and activated inverter circuits INV5 and INV6 in the slave latch circuit 12.

### REFERENCE TO RELATED APPLICATION

The present application is claiming the priority of the earlier Japanese patent application No. 2007-054382 filed on Mar. 5, 2007, the entire disclosure thereof being incorporated herein by reference thereto.

### FIELD OF THE INVENTION

The present invention relates to a master-slave type flip-flop circuit and latch circuit, and particularly to a master-slave type flip-flop circuit and latch circuit capable of reducing the power consumption in standby mode.

### BACKGROUND OF THE INVENTION

Conventionally, the power supplies of predetermined circuits are shut off during standby mode in order to reduce the power consumption of a semiconductor integrated circuit device. However, if the predetermined circuits include a flip-flop circuit or latch circuit, data held by the flip-flop circuit or latch circuit will be lost when the power supplies are simply turned off. A technology that turns off the power supply of only one of master latch or slave latch circuits in the flip-flop circuit so that the other circuit holds the data is known. Further, a technology that reduces the leak current that occurs while data is being held and decreases the power consumption by increasing the threshold voltage of a MOS transistor included in the circuit holding the data is known as well (for instance, refer to Patent Document 1).

FIG. 7 is a circuit diagram of a master-slave type flip-flop circuit described in Patent Document 1. In the master-slave type flip-flop circuit shown in FIG. 7, inverters 116 and 117 distribute clock signals CLKA and *CLKA to each part. Further, a master flip-flop is comprised of inverters I11 and I12, a P-channel MOS transistor TP11, and N-channel MOS transistors TN11 to TN13. In the master flip-flop, received data is stored by the inverters I11 and I12 in which an output one inverter is connected to an input of the other, respectively.

A slave flip-flop is comprised of inverters I13 and I14, a P-channel MOS transistor TP12, and N-channel MOS transistors TN14 and TN15. In the slave flip-flop, received data is stored by the inverters I13 and I14 in which an output of one inverter is connected to input of the other, respectively.

The P-channel MOS transistor TP11 and the N-channel MOS transistors TN11, TN12, TN14, and TN15 have low threshold values. The inverters I11, I12, I15, I16, and I17 are constituted by transistors with similarly low threshold values and are connected to a power supply VDD-V that can be shut off.

On the other hand, the P-channel MOS transistor TP12 and the N-channel MOS transistor TN13 have high threshold values. Further, the inverters I13 and I14 are constituted by P-channel MOS transistors and N-channel MOS transistors with high threshold values. Such inverters using N-channel MOS transistors and P-channel MOS transistors with high threshold values are indicated by diagram symbols with a boldface line as the inverter I13 in FIG. 7 and distinguished from the inverters constituted by the transistors with low threshold values and connected to the power supply that can be shut off.

The master-slave type flip-flop circuit configured as above can minimize the decrease in operating speed while reducing the power consumption during standby mode since the master flip-flop uses the inverters constituted by transistors with low threshold values and connected to the power supply that can be shut off. Further, the master-slave type flip-flop circuit can operate normally even during standby mode since the slave flip-flop uses the inverters that drive the output with transistors with high threshold values, resulting in a small leak current. Therefore, by having the circuit operate during standby mode, stored data will not be lost.

Meanwhile, a technology in a latch circuit that stores the signal of a predetermined node in a memory circuit via a switch circuit operated by a control circuit in a latch circuit during standby mode so as to hold the power supply of the memory circuit is known (for instance, refer to Patent Document 2).

[Patent Document 1]

Japanese Patent Kokai Publication No. JP-A-11-284493

[Patent Document 2]

Japanese Patent Kokai Publication No. JP-A-7-154228

### SUMMARY OF THE DISCLOSURE

The following analysis is given by the present invention. The entire disclosures of the above mentioned Patent Documents are herein incorporated by reference thereto.

In the master-slave type flip-flop circuit shown in FIG. 7, the power supplies (terminals) of the inverters I16 and I17 are connected to the power supply VDD-V that can be shut off. Therefore the power supplies of the inverters I16 and I17 are shut off during standby mode and the clock signals CLKA and *CLKA will have a potential level near a low level (see FIG. 7 of Patent Document 1). When the clock signal *CLKA has a potential level near the low level and the N-channel MOS transistor TN14 is turned off in the slave latch, data is held by the P-channel MOS transistor TP12 in an on state, provided that a node QE is at a low level. However, if the node QE is at a high level, the P-channel MOS transistor TP12 will be turned off. Further, since the potential level of the clock signal *CLKA is close to the low level, the N-channel MOS transistor TN14 is unlikely to stably remain in an on state and the data might not be held.

Further, in the master-slave type flip-flop circuit shown in FIG. 7, a standby signal *STB must be activated (being at a low level) when a clock signal CLK is at a low level. In other words, if the standby signal *STB is activated (being at the low level) when the clock signal CLK is at a high level, the N-channel MOS transistor TN13 will be turned off and data in the master latch circuit will not be sent to the slave latch. Thus, the power supply of the master latch circuit is shut off and the data in the master latch circuit will be lost.

Accordingly there is much to be desired in the art.

According to an aspect of the present invention, there is provided a master-slave type flip-flop circuit that receives and holds a data signal in synchronization with a clock signal. During standby mode, a power supply of either a master latch circuit or slave latch circuit is shut off and the other circuit holds data. And the flip-flop circuit comprises a clock input circuit that receives the clock signal and sets it to a predetermined logic value so that the held data does not change.

According to another aspect of the present invention, there is provided a latch circuit that receives and holds a data signal in synchronization with a clock signal. The latch circuit comprises a clock input circuit that receives power during standby mode. And the latch circuit receives said clock signal and sets it to a predetermined logic value so as to hold data.

According to a further aspect of the present invention, there is provided a semiconductor (integrated) circuit device that comprises at least one of the above master-slave type flip-flop circuit and the above latch circuit.

The meritorious effects of the present invention are summarized as follows.

According to the present invention, since a clock input circuit that receives a clock signal and sets it to a predetermined logic value in standby mode, during which the power consumption is reduced, is provided, data can be stably held regardless of when the circuit enters standby mode.

### BRIEF DESCRIPTION OF THE DRAWINGS

FIGS. 1A and 1B are circuit diagrams of a master-slave type flip-flop circuit relating to a first example of the present invention.

FIGS. 2A and 2B are equivalent circuit diagrams of a transfer gate and clocked inverter.

FIG. 3 is a circuit diagram of a master-slave type flip-flop circuit relating to a second example of the present invention.

FIG. 4 is a circuit diagram of a master-slave type flip-flop circuit relating to a third example of the present invention.

FIG. 5 is a circuit diagram of a master-slave type flip-flop circuit relating to a fourth example of the present invention.

FIG. 6 is a circuit diagram of a master-slave type flip-flop circuit relating to a fifth example of the present invention.

FIG. 7 is a circuit diagram of a conventional master-slave type flip-flop circuit.

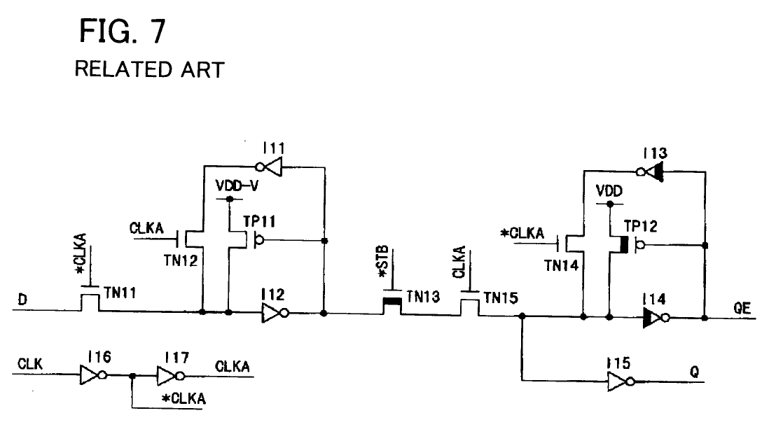

### PREFERRED MODES OF THE INVENTION

In the master-slave type flip-flop circuit and/or the latch circuit according to the above mentioned aspects of the present invention, following preferred modes are presented.

A master-slave flip-flop circuit may comprise: the latch circuit as either a master latch circuit or slave latch circuit, wherein the power supply of the other circuit is shut off during the standby mode.

A semiconductor integrated circuit device may comprise: the master-slave type flip-flop circuit.

A semiconductor integrated circuit device may comprise: the latch circuit.

A master-slave type flip-flop circuit relating to an example of the present invention receives and holds a data signal in synchronization with a clock signal. During standby mode, the power supply of either a master latch circuit or slave latch circuit is shut off, and the other circuit holds the data. It comprises a clock input circuit that receives the clock signal and sets it to a predetermined logic value so that the held data does not change.

Here, it is preferable that power be supplied to the clock input circuit even during standby mode.

Further, the clock input circuit may comprise a gate circuit that controls the clock signal according to a standby mode signal indicating the standby mode.

Further, the absolute value of a first threshold voltage of MOS transistors constituting the other circuit may be greater than the absolute value of a second threshold voltage of MOS transistors that constitute the rest of circuits.

Further, the absolute value of a third threshold voltage of MOS transistors constituting the clock input circuit may be less than the absolute value of the first threshold voltage, but greater than the absolute value of the second threshold voltage.

A set input circuit and/or reset input circuit to which power is supplied even during standby mode may be provided and the master latch circuit and/or the slave latch circuit may be respectively set and/or reset by the set input circuit and/or reset input circuit.

Each of the set input circuit and/or reset input circuit may comprise a gate circuit that controls a set signal and/or reset signal according to a standby mode signal indicating the standby mode.

The absolute value of the threshold voltage of MOS transistors constituting each of the set input circuit and/or reset input circuit may be greater than the absolute value of the second threshold voltage.

A latch circuit relating to another example of the present invention receives and holds a data signal in synchronization with a clock signal, and comprises a clock input circuit that receives power supply during standby mode and that receives the clock signal and sets it to a predetermined logic value so that the data will not be lost.

Here, the clock input circuit may comprise a gate circuit that controls the clock signal according to a standby mode signal indicating the standby mode.

The setting of the absolute values of the threshold voltages of the MOS transistors described above is applied to each threshold voltage of both N-channel transistors and P-channel transistors included in CMOS circuits. However, a setting where only the threshold value of a MOS transistor having more off-leak current is changed is permitted. The present invention will be further described in detail using examples with reference to the drawings.

### EXAMPLE 1

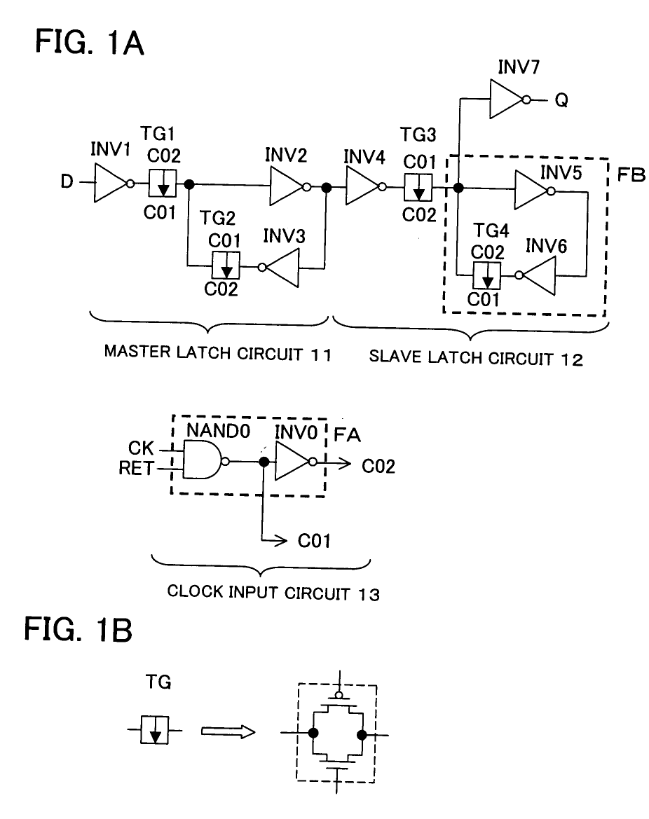

FIG. 1A is a circuit diagram of a master-slave type flip-flop circuit relating to a first example of the present invention. In FIG. 1A, the master-slave type flip-flop circuit is comprised of a master latch circuit 11, a slave latch circuit 12, and a clock input circuit 13. The master latch circuit 11 includes inverter circuits INV1, INV2, and INV3, and transfer gate circuits TG1 and TG2. Further, the slave latch circuit 12 includes inverter circuits INV4, INV5, and INV6, and transfer gate circuits TG3 and TG4. Further, the clock input circuit 13 includes a NAND circuit NAND0 and an inverter circuit INV0. Here, the transfer gate circuit is a CMOS switch circuit such as one shown in an equivalent circuit diagram in FIG. 1B. Or it may simply be an NMOS switch or PMOS switch.

In the clock input circuit 13, the NAND circuit NAND0 performs a NAND operation for a clock signal CK and a standby mode signal RET, i.e., NAND0 controls the clock signal CK using the standby mode signal RET, and outputs the result as a clock signal C01 to the master latch circuit 11 and the slave latch circuit 12. Further, the inverter circuit INV0 inverts the clock signal C01 and outputs the result as a (inverted) clock signal C02 to the master latch circuit 11 and the slave latch circuit 12.

First, the operation when the standby mode signal RET is at a high level, i.e., the operation in normal operation mode, will be described. In this case, the operation is the same as that of the conventional master-slave type flip-flop circuit.

When the clock signal CK is at a low level, the clock signal C01 is at a high level, and the clock signal C02 is at a low level, the transfer gate circuits TG1 and TG4 are turned on and the transfer gate circuits TG2 and TG3 are turned off. A data signal D is inverted by the inverter circuit INV1 and reinverted by the inverter circuit INV2 via the on-state transfer gate circuit TG1. An output of the inverter circuit INV2 is inverted by the inverter circuits INV3 and INV4, however, it is not sent beyond this point since the transfer gate circuits TG2 and TG3 are turned off.

Meanwhile, an output of the inverter circuit INV6 is fed to the inverter INV5 through the on-state transfer gate circuit TG4, in which the inverter circuit INV5 inverts the signal received from the transfer gate TG3. In other words, the data is held by a loop formed by the inverter circuits INV5 and INV6. The output of the inverter INV6 is inverted by the inverter circuit INV7 and outputted as an output signal Q.

When the clock signal CK changes to a high level, the clock signal C01 changes to a low level, and the clock signal C02 changes to a high level, the transfer gate circuits TG1 and TG4 are turned off and the transfer gate circuits TG2 and TG3 are turned on. Inputting of the data signal D is cut off by the off-state transfer gate circuit TG1. However, an output of the inverter circuit INV3 is fed to the inverter circuit INV2 through the on-state transfer gate circuit TG2. In other words, the logic value of the data signal D immediately before the clock signal CK changes to the high level is held by the loop formed by the inverter circuits INV2 and INV3.

Further, the output of the inverter circuit INV2, being further inverted by the inverter circuit INV4, is fed to the inverter circuits INV5 and INV7 through the on-state transfer gate circuit TG3. In other words, the output data of the inverter circuit INV2, which has been held, is outputted from the inverter circuit INV7 as the output signal Q. At this time, the output of the inverter circuit INV6 is not fed to the inverter circuit INV7 since the transfer gate circuit TG4 is turned off.

As described, in normal operation mode, when the clock signal CK is at a low level, the data is held by the loop formed in the slave latch circuit 12 and is outputted as the output signal Q. When the clock signal CK changes to a high level, the data signal D at the time of a positive edge of the clock signal CK is held by the master latch circuit 11 and is outputted as the output signal Q. Then, when the clock signal CK changes back to the low level, the transfer gate circuit TG4 is turned on and the slave latch circuit 12 will hold the data which has been held by the master latch circuit 11, as stated before.

Next, the operation when the standby mode signal RET is at a low level, i.e., the operation in standby mode, will be described.

In the clock input circuit 13, since the standby mode signal RET is now at the low level, the clock signal C01 and the clock signal C02 are kept at the high level and the low level, respectively, regardless of whether the clock signal is at the high level or low level. Therefore, as described before, the data is held by the loop formed by the inverter circuits INV5 and INV6 in the slave latch circuit 12.

Further, during standby mode, power continues to be supplied to an FA section (the NAND circuit NAND0 and the inverter circuit INV0, marked by a broken line) in the clock input circuit 13 and to an FB section (the inverter circuits INV5 and INV6 and the transfer gate circuit TG4, marked by a broken line) in the slave latch circuit 12, whereas the power supply to the other circuits is shut off. Therefore, the clock signal C01 stably remains at the high level and the clock signal C02 does so at the low level while the data is held by the loop formed by the on-state transfer gate circuit TG4 and the activated inverter circuits INV5 and INV6.

As described, by having the standby mode signal RET at a low level regardless of the level of the clock signal CK, data can be stably held regardless of timing. The operation can be restarted from this holding data state in the standby mode by changing the standby mode signal RET to the high level (normal mode).

Further, a threshold voltage (the first threshold voltage) of MOS transistors that constitute the circuits in the FB section may be set higher than a threshold voltage (the second threshold voltage) of other MOS transistors. By using such MOS transistors with a higher threshold voltage for the circuit in the FB section, which is activated during standby mode, the leak current of the MOS transistors can be decreased and the power consumption can be reduced. It should be noted that the circuit in the FB section is independent from a path extending from the data signal D to the output signal Q. Therefore, increasing the threshold voltage of the MOS transistors constituting the circuits in the FB section has almost no influence on the delay time, set-up timing, and hold timing of the flip-flop circuit.

Further, a threshold voltage (the third threshold voltage) of MOS transistor that constitute the circuits in the FA section may be set lower than the first threshold voltage but higher than the second threshold voltage. By using MOS transistors with such a threshold voltage for the circuit in the FA section, which is activated during standby mode, the leak current of the MOS transistors can be decreased and the power consumption can be reduced. Generally speaking, increasing the threshold voltage might cause a decrease in the operating speed. By setting the threshold voltage of the MOS transistors in the FA section, which is the clock input circuit 13 operating at high speed, lower than the threshold voltage of the MOS transistors in the FB section, the leak current can be reduced while the decrease in operating speed is minimized.

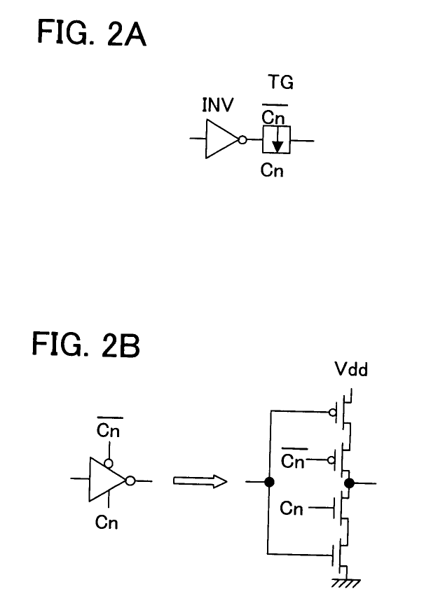

In the example above, transfer gate circuits are used as switch circuits. However, the present invention is not limited to this configuration, and a circuit formed of an inverter circuit and a transfer gate circuit connected to the output of the inverter circuit as shown in FIG. 2A may be replaced with a clocked inverter circuit shown in FIG. 2B. In this case, the similar combinations included in the master-slave type flip-flop circuit may be entirely or partially replaced. Note that all the examples described below use transfer gate circuits, however, they can be replaced with clocked inverter circuits as well.

Further, in the present description, the term “master latch circuit” denotes a section that includes the front stage of two stages of latch circuits connected in series that constitute a flip-flop circuit, and the term “slave latch circuit” denotes a section that includes the later stage. These terms are not limited to the circuits and scope shown in and indicated by FIGS. 1A and 1B.

### EXAMPLE 2

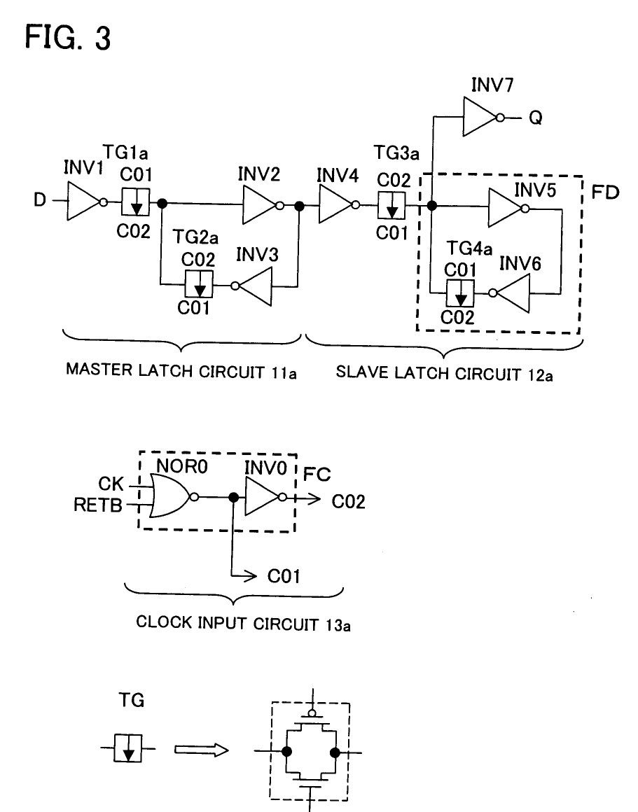

FIG. 3 is a circuit diagram of a master-slave type flip-flop circuit relating to a second example of the present invention. In FIG. 3, the symbols same as the ones in FIGS. 1A and 1B indicate the same things, thus the explanations of them will be omitted. The master-slave type flip-flop circuit shown in FIG. 3 is different from the first example, in which the data signal D is held using a positive edge of the clock signal CK, in that the data signal D is held using a negative edge of the clock signal CK.

In a clock input circuit 13a, a NOR circuit NOR0 performs a NOR operation for the clock signal CK and a standby mode signal RETB, i.e., NOR0 controls the clock signal CK using the standby mode signal RETB, and outputs the result as the clock signals C01 and C02 to a master latch circuit 11a and a slave latch circuit 12a. When the standby mode signal RETB is at a low level, it indicates normal operation mode, and when it is at a high level, it indicates standby mode.

For transfer gate circuits TG1a and TG2a included in the master latch circuit 11a and transfer gate circuits TG3a and TG4a included in the slave latch circuit 12a, the logic of the switch control is inverted from that for the transfer gate circuits TG1, TG2, TG3, and TG4 in FIG. 1A, respectively.

In the master-slave type flip-flop circuit configured as above, the slave latch circuit 12a holds the data in normal mode (the standby mode signal RETB at the low level) when the clock signal CK is at the high level. Further, when the clock signal CK changes to the low level from the high level (to form a negative edge), the data signal D at this point of time is held by the master latch circuit 11a. Then, when the clock signal CK is turned to the high level again, as stated before, the transfer gate circuit TG4a is turned on and the slave latch circuit 12a will hold the data which has been previously held by the master latch circuit 11a.

On the other hand, in the standby mode, i.e., when the standby mode signal RETB is at the high level, the clock signal C01 and the clock signal C02 are kept at the low level and the high level, respectively, regardless of the level of the clock signal CK. As a result, the on-state transfer gate circuit TG4a holds the data in the slave latch circuit 12a. At this time, power continues to be supplied to an FD section (the inverter circuits INV5 and INV6, the transfer gate circuit TG4a, marked by a broken line) in the slave latch circuit 12a and to an FC section (the NOR circuit NOR0 and the inverter circuit INV0, marked by a broken line) in the clock input circuit 13a whereas the power supply to the other circuits is shut off.

Further, a threshold voltage of MOS transistors that constitute the circuit in the FD section is set similarly as in the FB section in FIG. 1A, and a threshold voltage of MOS transistors that constitute the circuits in the FC section is set similarly as in the FA section in FIG. 1A. By employing these settings, the leak current can be reduced as in the first example.

### EXAMPLE 3

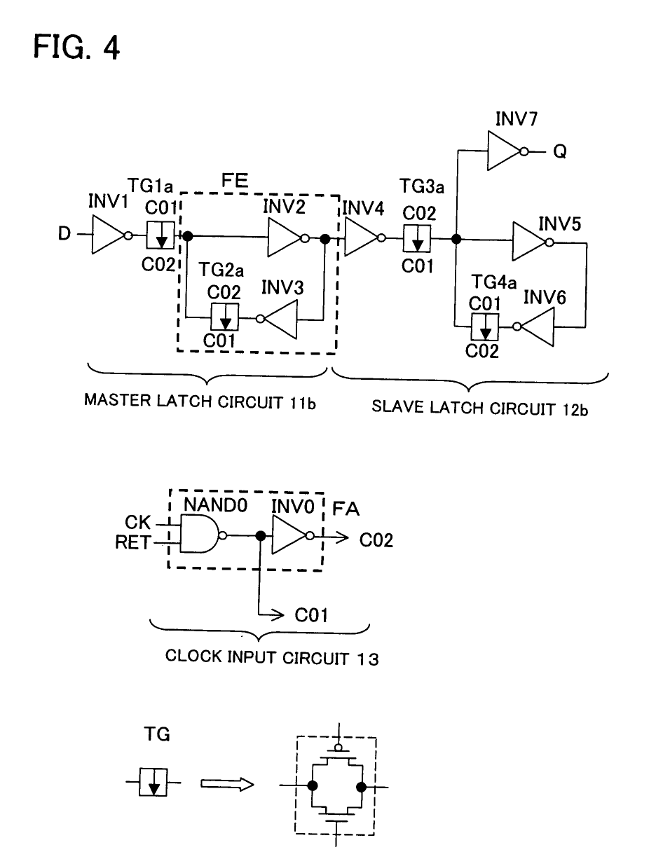

FIG. 4 is a circuit diagram of a master-slave type flip-flop circuit relating to a third example of the present invention. In FIG. 4, the symbols same as the ones in FIGS. 1A, 1B and 3 indicate the same things, thus the explanations of them will be omitted. The master-slave type flip-flop circuit shown in FIG. 4 is different from the first and second examples in that the data signal D is held using a negative edge of the clock signal CK and a master latch circuit 11b holds the data in the standby mode.

The configurations of the master latch circuit 11b and a slave latch circuit 12b are almost identical to the master latch circuit 11a and the slave latch circuit 12a in FIG. 3, respectively. However, the differences reside in that the threshold voltage of MOS transistors that constitute the circuits in an FE section (the inverter circuits INV2 and INV3, and the transfer gate circuit TG2a, marked by a broken line) in the master latch circuit 11b is set similarly as in the FB section in FIG. 1A, and the threshold voltage of MOS transistors in the slave latch circuit 12b is set low.

In the master-slave type flip-flop circuit configured as above, the data is held by the master latch circuit 11b and is outputted as the output signal Q via the inverter circuit INV4, the on-state transfer gate circuit TG3a, and the inverter circuit INV7 in normal mode (where the standby mode signal RET is at the high level) when the clock signal CK is at the low level. Further, when the clock signal CK is at the high level, the data signal D is latched by the master latch circuit 11b and the data which has been previously held by the master latch circuit 11b is now held by the slave latch circuit 12b. Thereafter, when the clock signal CK changes from the high level to the low level (to form a negative edge), the data signal D at this point of time is held by the master latch circuit 11b.

On the other hand, in the standby mode, i.e., when the standby mode signal RET is at the low level, the clock signal C01 and the clock signal C02 are kept at the high level and the low level, respectively regardless of the level of the clock signal CK. As a result, the on-state transfer gate circuit TG2a holds the data in the master latch circuit 11b. At this time, power continues to be supplied to the FE section and the FA section whereas the power supply to the other circuits is shut off.

Further, by setting the threshold voltage of MOS transistors that constitute the circuits in the FE section in the master latch circuit 11b similarly as in the FB section in FIG. 1A, the leak current can be reduced as described in the first example.

It should be noted that the master-slave type flip-flop circuit relating to the first example needs to be in the standby mode when the clock signal CK is at the low level. On the other hand, the master-slave type flip-flop circuit relating to the second example needs to be in the standby mode when the clock signal CK is at the high level. Furthermore, the master-slave type flip-flop circuit relating to the third example needs to be in the standby mode when the clock signal CK is at the low level. This means that the timing of entering the standby mode cannot be determined if the master-slave type flip-flop circuits relating to the first and second examples are mixed in the same clock domain. On the other hand, the master-slave type flip-flop circuits relating to the first and third examples can be mixed in the same clock domain by the provision that they both enter into the standby mode when the clock signal CK is at the low level.

### EXAMPLE 4

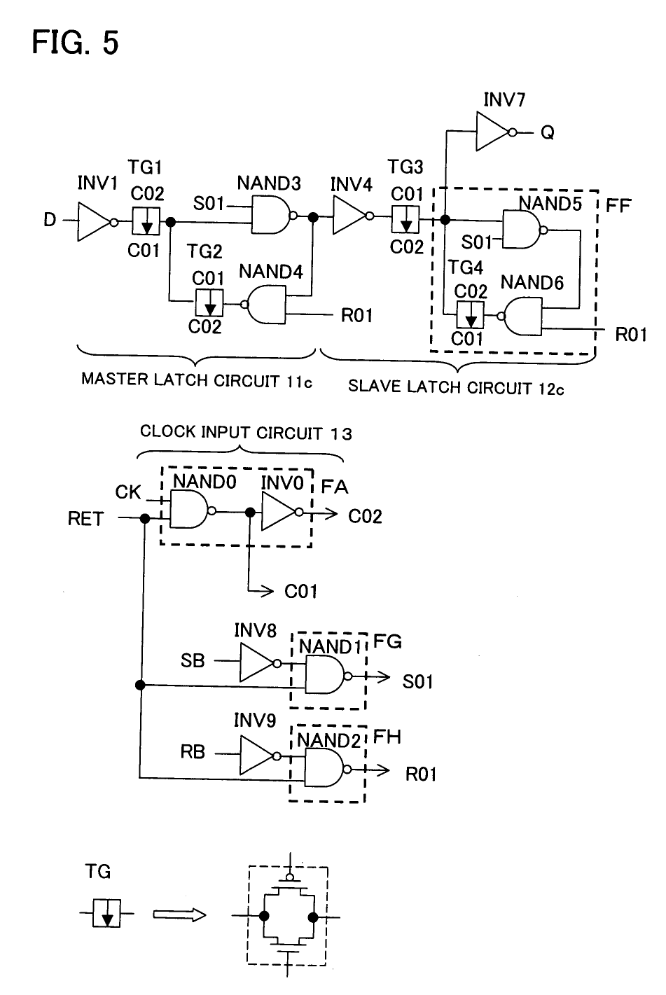

FIG. 5 is a circuit diagram of a master-slave type flip-flop circuit relating to a fourth example of the present invention. In FIG. 5, the symbols same as the ones in FIGS. 1A and 1B indicate the same things, thus the explanations of them will be omitted. The master-slave type flip-flop circuit shown in FIG. 5 has set/reset capabilities.

A set signal SB is fed to one of input ends of a NAND circuit NAND1 via an inverter circuit INV8. Further, a reset signal RB is fed to one of input ends of a NAND circuit NAND2 via an inverter circuit INV9. The other input ends of the NAND circuits NAND1 and NAND2 receive the standby mode signal RET. An output of the NAND circuit NAND1 is fed to one of input ends of NAND circuits NAND3 and NAND5 as a signal S01. Further, an output of the NAND circuit NAND2 is fed to one of input ends of NAND circuits NAND4 and NAND6 as a signal R01.

The NAND circuits NAND3 and NAND4 are included in a master latch circuit 11c, and they replace the inverter circuits INV2 and INV3 in FIG. 1A, respectively. Further, the NAND circuits NAND5 and NAND6 are included in a slave latch circuit 12c, and they replace the inverter circuits INV5 and INV6 in FIG. 1A, respectively.

When the set signal SB and the reset signal RB are both at a high level, the signals S01 and R01 both go to a high level and the master-slave type flip-flop circuit configured as above operates as described in the first example.

In normal mode, i.e., when the standby mode signal RET is at the high level, if the set signal SB goes to a low level, the signal S01 will go to a low level and outputs of the NAND circuits NAND3 and NAND5 will go to a high level unconditionally. When the transfer gate circuit TG3 is turned on and the transfer gate circuit TG4 is turned off, the output of the NAND circuit NAND3 is fed to the inverter circuit INV7 via the inverter circuit INV4 and the output signal Q goes to a high level, meaning it is in a set state. When the transfer gate circuit TG3 is turned off and the transfer gate circuit TG4 is turned on, the output of the NAND circuit NAND5 is fed to the inverter circuit INV7 via the NAND circuit NAND6 and the output signal Q goes to the high level, meaning it is in a set state. However, in this case, the reset signal RB is assumed to be at the high level, i.e., the signal R01, which is fed to one of the input ends of the NAND circuit NAND6, is at the high level.

Further, in the normal mode, i.e., when the standby mode signal RET is at the high level, if the reset signal RB goes to a low level, the signal R01 will go to a low level and outputs of the NAND circuits NAND4 and NAND6 will go to a high level unconditionally. When the transfer gate circuit TG4 is turned on and the transfer gate circuit TG2 is turned off, the output of the NAND circuit NAND6 is fed to the inverter circuit INV7 and the output signal Q goes to a low level, meaning it is in a reset state. Further, when the transfer gate circuit TG4 is turned off and the transfer gate circuit TG2 is turned on, the transfer gate circuit TG1 is turned off. As a result, the output of the NAND circuit NAND4 is fed to the inverter circuit INV7 via the NAND circuit NAND3, the inverter circuit INV4, and the on-state transfer gate circuit TG3 and the output signal Q goes to the low level, meaning it is in a reset state. However, in this case, the set signal SB is assumed to be at the high level, i.e., the signal S01, which is fed to one of the input ends of the NAND circuit NAND3, is at the high level.

In the standby mode, i.e., when the standby mode signal RET is at the low level, power is supplied to an FG section, which is the NAND circuit NAND1, and an FH section, which is the NAND circuit NAND2. As a result, the signals S01 and R01 unconditionally go to the high level and there will be no influence on the data holding operation of the slave latch circuit 12c. Further, power is also supplied to an FF section (the NAND circuits NAND5 and NAND6, and the transfer gate circuit TG4, marked by a broken line) in the slave latch circuit 12c and the FA section, whereas the power supply to the circuits other than the FF section, the FA section, and the NAND circuits NAND1 and NAND2 is shut off.

Further, the threshold voltage of MOS transistors that constitute the circuits in the FF section is set similarly as in the FB section in FIG. 1A. By employing this setting, the leak current can be reduced as described in the first example. Further, it is preferable that the threshold voltage of MOS transistors that constitute the circuits in the FG section (the NAND circuit NAND1) and the FH section (the NAND circuit NAND2) be set similarly as in the FB section in FIG. 1A.

The circuit described above has set/reset capabilities, however, it may comprise only one of the capabilities. A master-slave type flip-flop circuit with a reset capability can be configured by removing the inverter INV8 and the NAND circuit NAND1, and having inverter circuits constitute the NAND circuits NAND3 and NAND5. Further, a master-slave type flip-flop circuit with a set capability can be configured by removing the inverter INV9 and the NAND circuit NAND2, and having inverter circuits constitute the NAND circuits NAND4 and NAND6.

### EXAMPLE 5

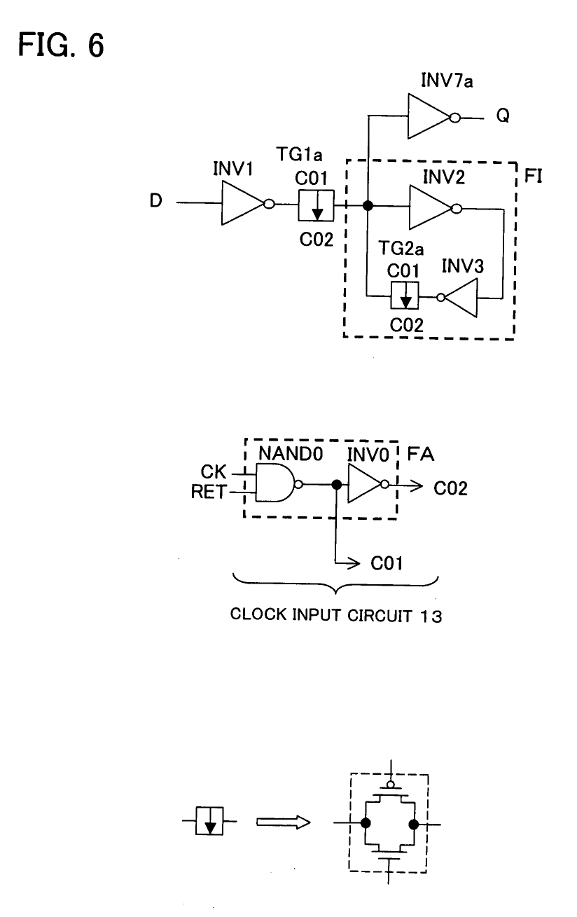

FIG. 6 is a circuit diagram of a latch circuit relating to a fifth example of the present invention. In FIG. 6, the symbols same as the ones in FIG. 4 indicate the same things, thus the explanations of them will be omitted. The latch circuit shown in FIG. 6 is the master latch circuit 11b in FIG. 4 simply functioning as a latch circuit and it inverts a signal fed to the input end of the inverter circuit INV2 with an inverter circuit INV7a so as to output the result as the output signal Q. It can also be viewed as the slave latch circuit 12 taken out from the master-slave type flip-flop circuit in FIG. 1A.

In the latch circuit configured as above, in the normal mode, i.e., when the standby mode signal RET is at the high level, the data signal D is latched by the inverter circuit INV1, the on-state transfer gate circuit TG1a, and the inverter circuit INV2 when the clock signal CK changes from the low level to the high level (a positive edge). Further, when the clock signal CK is at the low level, the latched data is held by the on-state transfer gate circuit TG2a in a loop formed by the inverter circuits INV2 and INV3.

On the other hand, in the standby mode, i.e., when the standby mode signal RET is at the low level, the clock signals C01 and C02 are kept at the high level and low level respectively regardless of the level of the clock signal CK. As a result, the data continues to be held. At this time, power continues to be supplied to an FI section (the inverter circuits INV2 and INV3, and the transfer gate circuit TG2a, marked by a broken line) and the FA section whereas the power supply to the circuits other than the FI and FA sections is shut off.

Further, by setting the threshold voltage of MOS transistors that constitute the circuits in the FI section similarly as in the FB section in FIG. 1A, the leak current can be reduced as described in the first example.

A semiconductor integrated circuit device including the master-slave type flip-flop circuit or latch circuit described above comprises a clock input circuit that receives a clock signal and sets it to a predetermined logic value in standby mode, during which the power consumption is reduced. As a result, the data can be stably held regardless of when the circuit enters standby mode.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A master-slave type flip-flop circuit comprising a master flip-flop circuit and a slave flip-flop circuit;
wherein said master-slave type flip-flop circuit receives and holds a data signal in synchronization with a clock signal, and wherein, during standby mode, a power supply of either a master latch circuit or slave latch circuit is shut off, and the other circuit holds data;
said master-slave type flip-flop circuit comprising:
a clock input circuit that receives said clock signal and sets it to a predetermined logic value so that said held data does not change.

2. The master-slave type flip-flop circuit as defined in claim 1 wherein power is supplied to said clock input circuit during said standby mode.

3. The master-slave type flip-flop circuit as defined in claim 1 wherein said clock input circuit comprises a gate circuit that controls a clock signal using a standby mode signal indicating said standby mode.

4. The master-slave type flip-flop circuit as defined in claim 2 wherein said clock input circuit comprises a gate circuit that controls a clock signal using a standby mode signal indicating said standby mode.

5. The master-slave type flip-flop circuit as defined in claim 1 wherein an absolute value of a first threshold voltage of MOS transistors that constitute said other circuit is greater than an absolute value of a second threshold voltage of MOS transistors that constitute the rest of the circuit.

6. The master-slave type flip-flop circuit as defined in claim 5 wherein an absolute value of a third threshold voltage of MOS transistors that constitute said clock input circuit is less than the absolute value of said first threshold voltage, but greater than the absolute value of said second threshold voltage.

7. The master-slave type flip-flop circuit as defined in claim 5 comprising a set input circuit and/or reset input circuit to which power is supplied during said standby mode wherein said set input circuit and/or reset input circuit put said master latch circuit and/or slave latch circuit into a set state and/or reset state respectively.

8. The master-slave type flip-flop circuit as defined in claim 6 comprising a set input circuit and/or reset input circuit to which power is supplied during said standby mode wherein said set input circuit and/or reset input circuit put said master latch circuit and/or slave latch circuit into a set state and/or reset state respectively.

9. The master-slave type flip-flop circuit as defined in claim 7 wherein each of said set input circuit and/or reset input circuit comprises a gate circuit that controls a set signal and/or reset signal using a standby signal indicating said standby mode.

10. The master-slave type flip-flop circuit as defined in claim 9 wherein an absolute value of a threshold voltage of MOS transistors that constitute said set input circuit and/or reset input circuit is greater than the absolute value of said second threshold voltage.

11. A latch circuit comprising:
a clock input circuit that receives power during standby mode;
wherein said latch circuit receives and holds a data signal in synchronization with a clock signal;
said latch circuit receiving said clock signal and setting the received clock signal to a predetermined logic value so as to hold data.

12. The latch circuit as defined in claim 11 wherein said clock input circuit comprises a gate circuit that controls a clock signal using a standby mode signal indicating said standby mode.

13. A master-slave flip-flop circuit, comprising:
the latch circuit as defined in claim 11 as either a master latch circuit or slave latch circuit, that shuts off the power supply of the other circuit during said standby mode.

14. A master-slave flip-flop circuit, comprising:
the latch circuit as defined in claim 12 as either a master latch circuit or slave latch circuit, wherein the power supply of the other circuit is shut off during said standby mode.

15. A semiconductor integrated circuit device comprising: the master-slave type flip-flop circuit as defined in claim 1.

16. A semiconductor integrated circuit device comprising: the master-slave type flip-flop circuit as defined in claim 13.

17. A semiconductor integrated circuit device comprising: the master-slave type flip-flop circuit as defined in claim 14.

18. A semiconductor integrated circuit device comprising: the latch circuit as defined in claim 11.

19. A semiconductor integrated circuit device comprising: the latch circuit as defined in claim 12.
